(19) United States
(12) Patent Application Publication
(10) Pub. No.: US 2015/0138739 A1
(43) Pub. Date: May 21, 2015

(54) SUSPENSION BOARD WITH CIRCUIT

(71) Applicant: NITTO DENKO CORPORATION, Osaka (JP)

(72) Inventor: Tomoaki HISHIKI, Osaka (JP)

(73) Assignee: NITTO DENKO CORPORATION, Osaka (JP)

(21) Appl. No.: 14/520,973

(22) Filed: Oct. 22, 2014

(30) Foreign Application Priority Data
Nov. 15, 2013 (JP) 2013-237229

(51) Int. Cl. H05K 3/30; H05K 1/11; H05K 1/18

(52) U.S. Cl. CPC H05K 3/305; H05K 1/181; H05K 1/11; H05K 2201/10984; H05K 2201/2063
USPC 361/760

(57) ABSTRACT

A suspension board with circuit includes an electronic element, and a mounting portion having a terminal portion electrically connected to the electronic element. The electronic element and the mounting portion are bonded to each other via an adhesive containing a metal ion scavenger.

### CROSS-REFERENCE TO RELATED APPLICATION

The present application claims priority from Japanese Patent Application No. 2013-237229 filed on Nov. 15, 2013, the content of which is herein incorporated by reference into this application.

### BACKGROUND OF THE INVENTION

1. Field of the Invention

The present invention relates to a suspension board with circuit, and particularly to suspension board with circuit mounted in a hard disk drive.

2. Description of the Related Art

Conventionally, it has been proposed to mount various electronic elements on a suspension board with circuit. Specific examples of such electronic elements include a microactuator having a piezoelectric element such as a piezo-element for precisely and finely adjusting the position and angle of a magnetic head (see, e.g., Japanese Unexamined Patent No. 2007-141434).

In such a suspension board with circuit having a piezoelectric element as described in Japanese Unexamined Patent No. 2007-141434, by extending/contracting a piezoelectric element, a slider to which a magnetic head is fixed can be moved. As a result, a connection portion at which the piezoelectric element is electrically connected to the electrode of the suspension hoard with circuit is prone to breakage.

To prevent the breakage by mechanically reinforcing the connection portion, a head gimbal assembly has been proposed which has, e.g., a stage, piezoelectric elements for moving the stage, a transmission wiring portion having connection pads for the piezoelectric elements, connection portions physically and electrically connecting electrodes and the connection pads to each other, adhesive fixed portions each made of an insulating adhesive and adhesively fixed to the transmission wiring portion, and encapsulating portions covering the connection portions (see, e.g., Japanese Unexamined Patent No. 2011-129220 (FIG. 6B)).

### SUMMARY OF THE INVENTION

However, in the assembly of Japanese Unexamined Patent No. 2011-129220, the metal ions of the conductive material contained in the connection portions flow or move from the connection portions into the encapsulating portions or to the interfaces of the connection portions (occurrence of metal ion migration). This consequently causes the problem of the short-circuit of the piezoelectric elements with a metal part (e.g., metal supporting board) other than the connection portions. Accordingly, the reliability of electrical connection between the piezoelectric elements and terminal portions connecting the piezoelectric elements, such as the connection pads, is insufficient.

It is therefore an object of the present invention to provide a suspension board with circuit which allows an improvement in the reliability of electrical connection between an electronic element and a terminal portion.

A suspension board with circuit of the present invention includes an electronic element, and a mounting portion having a terminal portion electrically connected to the electronic element, wherein the electronic element and the mounting portion are bonded to each other via an adhesive containing a metal ion scavenger.

In the suspension board with circuit of the present invention, it is preferable that the adhesive containing the metal ion scavenger is an insulating adhesive.

In the suspension board with circuit of the present invention, it is preferable that the electronic element and the terminal portion are bonded to each other via a conductive adhesive.

In the suspension board with circuit of the present invention, it is preferable that the electronic element and the terminal portion are placed to face each other with the conductive adhesive being interposed therebetween, and the insulating adhesive is placed adjacent to the electronic element and the conductive adhesive so as to cover the electronic element and the conductive adhesive.

In the suspension board with circuit of the present invention, it is preferable that the metal ion scavenger is at least one selected from the group consisting of a nitrogen-containing compound, a hydroxyl group-containing compound, a carboxyl group-containing compound, an inorganic cation exchanger, a chelate agent, and a phosphorus- or sulfur-containing compound.

In the suspension board with circuit of the present invention, it is preferable that the nitrogen-containing compound is at least one selected from the group consisting of a triazole compound, a tetrazole compound, a pyridyl compound, and a triazine compound.

In the suspension board with circuit of the present invention, it is preferable that the hydroxyl group-containing compound is at least one selected from the group consisting of a quinol compound, a hydroxyanthraquinone compound, a polyphenolic compound, and a higher alcohol.

In the suspension board with circuit of the present invention, it is preferable that the carboxyl group-containing compound is at least one selected from the group consisting of a carboxyl group-containing aromatic compound and a carboxyl group-containing aliphatic acid compound.

In the suspension board with circuit of the present invention, it is preferable that the inorganic cation exchanger is at least one selected from the group consisting of an oxidized hydrate of an element selected from antimony, bismuth, zirconium, titanium, tin, magnesium, and aluminum, an aluminosilicate, a polyvalent metal acid salt, a heteropoly acid, hydrotalcite, and hydroxyapatite.

In the suspension board with circuit of the present invention, it is preferable that the chelate agent is at least one selected from the group consisting of an aminocarboxylic acid-type chelate agent and a phosphonic acid-type chelate agent.

In the suspension board with circuit of the present invention, it is preferable that the phosphorus- or sulfur-containing compound is at least one selected from the group consisting of an organophophate ester, an organophosphite ester, an organic sulfonate, an organic sulfur compound, a zinc dithiophosphate, and a phytic acid.

In the suspension board with circuit of the present invention, it is preferable that the insulating adhesive contains an insulating adhesive composition and the metal ion scavenger, and a content of the metal ion scavenger based on 100 parts by mass of the insulating adhesive composition is not less than 0.1 parts by mass and not more than 50 parts by mass.

The suspension board with circuit of the present invention includes the electronic element, and the mounting portion having the terminal portion electrically connected to the electronic element. The electronic element and the mounting portion are bonded to each other via the adhesive containing the metal ion scavenger. This allows the metal ion scavenger to capture the metal ions contained in a connection portion electrically connecting the electronic element and the terminal portion. As a result, it is possible to inhibit the metal ions from moving or flowing to the outside of the mounting portion. Therefore, it is possible to improve the reliability of the electrical connection between the electronic element and the terminal portion.

### BRIEF DESCRIPTION OF THE DRAWINGS

FIG. 1 shows a plan view of an embodiment of a suspension board with circuit of the present invention;

FIG. 2 shows an enlarged plan view of the suspension board with circuit shown in FIG. 1;

FIG. 3 shows a cross-sectional view of the suspension board with circuit shown in FIG. 2, which is taken along the line A-A; and

FIGS. 4A to 4D are production process views illustrating a method of producing the embodiment of the suspension board with circuit,

FIG. 4A showing the step of preparing the suspension board with circuit,

FIG. 4B showing the step of placing a conductive adhesive layer,

FIG. 4C showing the step of mounting piezo-elements, and

FIG. 4D showing the step of placing an insulating adhesive layer.

### DETAILED DESCRIPTION OF THE INVENTION

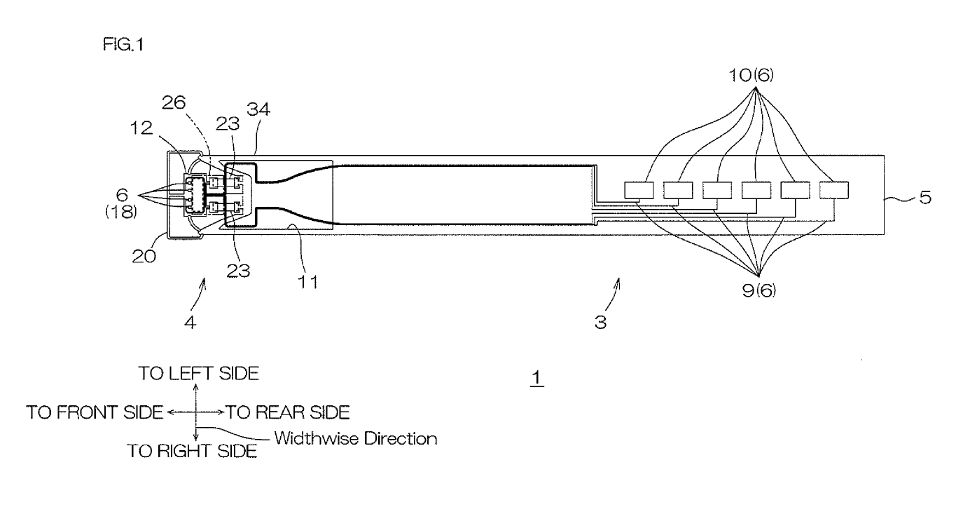

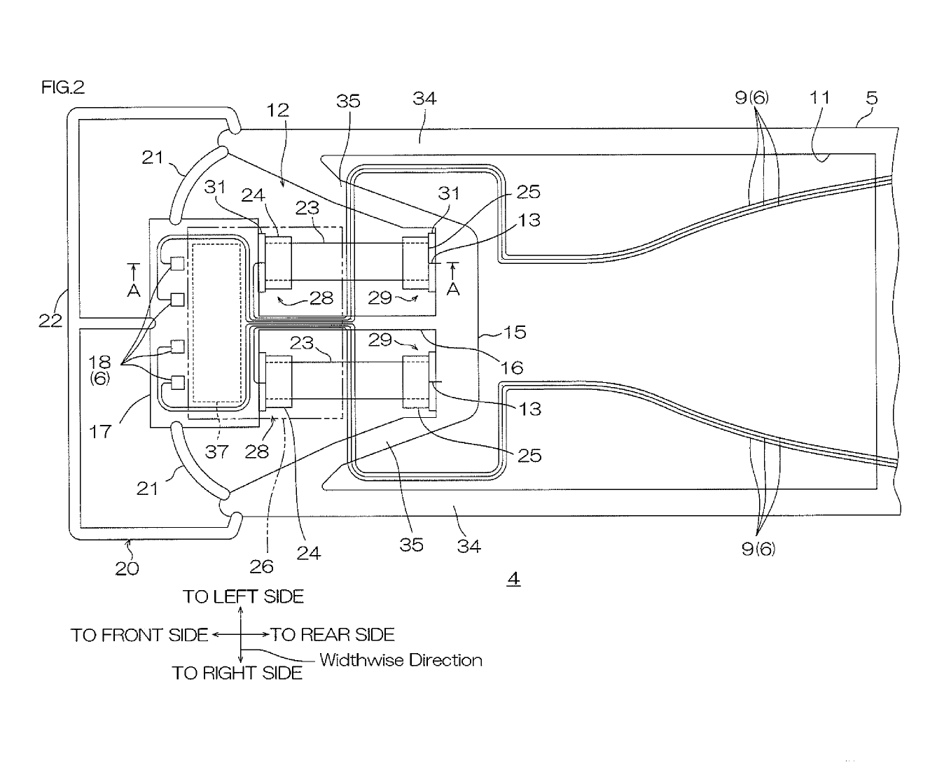

In FIG. 1, the upper and lower sides of the surface of the paper sheet with the drawing are respectively assumed to be a left side (one side in a first direction) and a right side (the other side in the first direction), the left and right sides thereof are respectively assumed to be a front side (one side in a second direction) and a rear side (the other side in the second direction), and the front and back sides in the depth direction thereof are respectively assumed to be an upper side (one side in a third direction or one side in a thickness direction) and a lower side (the other side in the third direction or the other side in the thickness direction). The drawings of FIGS. 2 to 4 are also based on the directions in FIG. 1.

In FIGS. 1 and 2, an insulating base layer 7 and an insulating cover layer 8 each described later are omitted to clearly show the relative positioning of a conductive layer 6 and a slider 26 each described later.

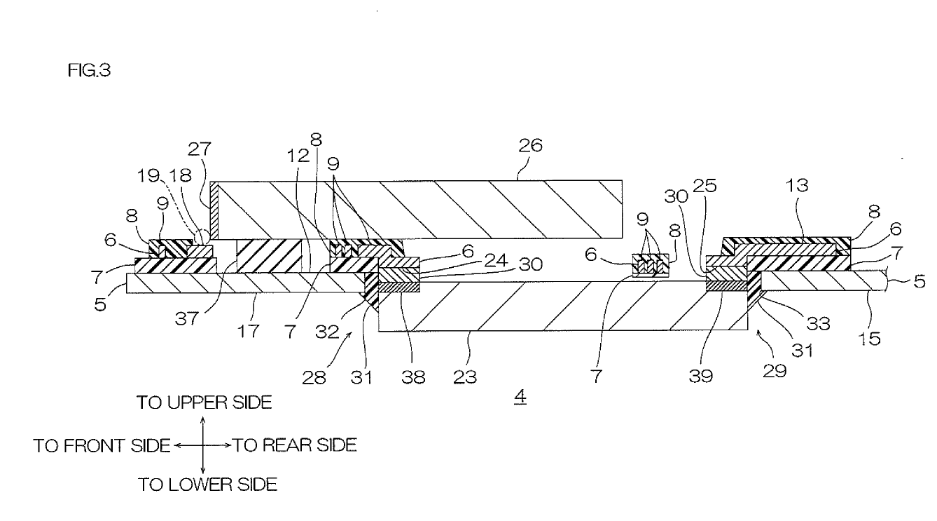

On a suspension board with circuit 1, the slider 26 (the imaginary line of FIG. 2 and the solid line of FIG. 3) on which a magnetic head 27 (FIG. 3) is mounted and piezo-elements 23 (piezoelectric elements) each as an electronic element are mounted.

In the suspension board with circuit 1, the conductive layer 6 is supported on a metal supporting board 5.

The metal supporting board 5 is formed in a generally rectangular flat belt shape in plan view extending in a longitudinal direction and integrally includes a main body portion 3 and a gimbal portion 4 formed on the front side (one side in the longitudinal direction, the same holds true hereinafter).

The main body portion 3 is formed in a generally rectangular shape in plan view.

The gimbal portion 4 is formed so as to frontwardly extend from the front end of the main body portion 3. The gimbal portion 4 is also formed with a board opening 11 having a generally rectangular shape in plan view and extending through the gimbal portion 4 in the thickness direction.

The gimbal portion 4 includes outrigger portions 34 defined outside the board opening 11 in a widthwise direction (left-right direction perpendicular to a front-rear direction), and a tongue portion 12 coupled to the outrigger portions 34.

The outrigger portions 34 are formed so as to linearly extend from the both widthwise end portions of the main body portion 3 toward the front side.

As shown in FIG. 2, the tongue portion 12 is provided widthwise inwardly of the outrigger portions 34 and coupled to the outrigger portions 34 via first coupling portions 35 extending widthwise inwardly and obliquely rearwardly from the front end portions of the outrigger portions 34. The tongue portion 12 is formed in a generally H-shaped shape in plan view and includes a base portion 15 having a generally rectangular shape in plan view extending long in the widthwise direction, a stage 17 located on the front side of the base portion 15 to be spaced apart therefrom and having a generally rectangular shape in plan view extending long in the widthwise direction, and a middle portion 16 connecting the base portion 15 and the widthwise middle portion of the stage 17 and having a generally rectangular shape in plan view which is long in the front-rear direction.

On the middle portion of the stage 17 in the widthwise and front-rear directions, as shown by the broken line of FIG. 2 and in FIG. 3, a stage adhesive layer 37 made of a known adhesive is placed. The stage 17 is connected to the outrigger portions 34 by a second coupling portion 20.

The second coupling portion 20 includes curved portions 21 which curvedly couple the respective front ends of the outrigger portions 34 to the both widthwise ends of the stage 17 and an E-shaped portion 22 which couples the respective front ends of the outrigger portions 34 to the front end of the stage 17.

The curved portions 21 curvedly extend widthwise inwardly and obliquely frontwardly from the respective front ends of the outrigger portions 34 to reach the both widthwise end portions of the stage 17.

The E-shaped portion 22 has a generally E-shaped shape in plan view. Specifically, the E-shaped portion 22 extends from the front ends of the both outrigger portions 34 toward the front side to subsequently bend widthwise inwardly. After extending widthwise inwardly, the portions of the E-shaped portion 22 extending from the front ends of the outrigger portions 34 toward the front side are united and then bent rearwardly to reach the front end of the stage 17.

The middle portion 16 is formed narrow and bendable in the widthwise direction.

As shown in FIG. 1, the conductive layer 6 includes external-side terminals 10, head-side terminals 18, front-side piezo-terminals 24 (FIG. 2) each as a terminal portion, rear-side piezo-terminals 25 each as the terminal portion (FIG. 2), wires 9, and ground wires 13.

The external-side terminals 10 are provided on the rear end portion of the main body portion 3. The plurality of (six) external-side terminals 10 are disposed to be spaced apart from each other in the front-rear direction.

As shown in FIG. 2, the head-side terminals 18 are provided on the front end portion of the stage 17. The plurality of (four) head-side terminals 18 are disposed to be spaced apart from each other in the widthwise direction.

The plurality of (two) front-side piezo-terminals 24 are disposed to be spaced apart from each other on both outsides of the middle portion 16 in the widthwise direction. The front-side piezo-terminals 24 are disposed rearwardly of the rear end edges of the widthwise outer portions of the stage 17 to be barely spaced apart therefrom. Each of the front-side piezo-terminals 24 is formed in a generally rectangular shape in plan view. That is, the front-side piezo-terminals 24 are formed such that the wires 9 (described later) at the rear end portions of the stage 17 protrude from the rear end edges of the stage 17 toward the rear side and extend widthwise outwardly.

As specifically shown in FIG. 3, the insulating base layer 7 protrudes rearwardly from the rear end edge of the stage 17 as described later, and the front-side piezo-terminals 24 are formed continuously from the wires 9 so as to protrude rearwardly of the insulating base layer 7. Between the wires 9 and the front-side piezo-terminals 24 protruding from the wires 9, stepped portions are formed such that the front-side piezo-terminals 24 are located under the wires 9. The front-side piezo-terminals 24 are formed such that the lower surfaces thereof are in contact with the conductive adhesive layer 30 (described later), the front side surfaces thereof are in contact with the insulating base layer 7, the front-side upper surfaces thereof are in contact with the insulating cover layer 8, and the rear side surfaces and rear-side upper surfaces thereof are exposed to the outside.

The front-side piezo-terminals 24 are also formed such that the lower surfaces thereof are located slightly above the lower surface of the insulating base layer 7 (described later) located adjacent thereto.

Over the lower surface and exposed surfaces (rear side surface and rear-side upper surface) of each of the front-side piezo-terminals 24, a plurality of (two) plating layers (not shown) are laminated. Specifically, a nickel plating layer is laminated so as to cover the front-side piezo-terminal 24 and a gold plating layer is laminated so as to cover the entire surface of the nickel plating layer.

As shown in FIG. 2, the rear-side piezo-terminals 25 are formed to correspond to the front-side piezo-terminals 24. The rear-side piezo-terminals 25 are formed on the rear side of the respective front-side piezo-terminals 24 to be spaced apart therefrom. The rear-side piezo-terminals 25 are disposed frontwardly of the front end edges of the widthwise outer portions of the base portion 15 to be barely spaced apart therefrom. Each of the rear-side piezo-terminals 25 is formed in a generally rectangular shape. That is, the rear-side piezo-terminals 25 are formed such that the conductive layer 6 protrudes from the front end edge of the base portion 15 toward the front side and extends widthwise outwardly.

As specifically shown in FIG. 3, the insulating base layer 7 protrudes frontwardly from the front end edge of the base portion 15, and the rear-side piezo-terminals 25 are formed continuously from the ground wires 13 (described later) so as to protrude frontwardly of the insulating base layer 7. Between the wires 9 and the rear-side piezo-terminals 25 protruding from the wires 9, stepped portions are formed such that the rear-side piezo-terminals 25 are located under the wires 9. The rear-side piezo-terminals 25 are formed such that the lower surfaces thereof are in contact with the conductive adhesive layer 30 (described later), the rear side surfaces thereof are in contact with the insulating base layer 7, the rear-side upper surfaces thereof are in contact with the insulating cover layer 8, and the front side surfaces and front-side upper surfaces thereof are exposed to the outside.

The rear-side piezo-terminals 25 are also formed such that the lower surfaces thereof are located slightly above the lower surface of the insulating base layer 7 located adjacent thereto.

Over the lower surface and exposed surfaces (front side surface and front-side upper surface) of each of the rear-side piezo-terminals 25, a plurality of (two) plating layers (not shown) are laminated. Specifically, a nickel plating layer is laminated so as to cover the rear-side piezo-terminal 25 and a gold plating layer is laminated so as to cover the entire surface of the nickel plating layer.

Note that the rear-side piezo-terminals 25 are provided independently of the wires 9 and grounded via the ground wires 13.

As shown in FIGS. 1 and 2, the wires 9 are continued to the external-side terminals 10, the head-side terminals 18, and the front-side piezo-terminals 24 to provide electrical connection therebetween.

As shown in FIG. 1, the plurality of (six) wires 9 are formed so as to be widthwise spaced apart from each other in the main body portion 3.

Specifically, the wires 9 are formed to extend from the external-side terminals 10 toward the front side in the rear end portion of the main body portion 3, bend midway in the main body portion 3 in the front-rear direction, while being divided into two branches, and extend toward the widthwise both end portions. Then, at the widthwise both end portions, the wires 9 are bent toward the front side to extend along the widthwise outer end edges toward the front end portion of the main body portion 3 and pass through the board opening 11 and the first coupling portions 35 and subsequently between the front-side piezo-terminals 24 and the rear-side piezo-terminals 25 in the gimbal portion 4, as shown in FIG. 2. Then, the wires 9 are converged midway in the middle portion 16 in the front-rear direction and bent toward the front side to subsequently extend frontwardly along the middle portion 16. Then, in the rear end portion of the stage 17, the wires 9 bend, while being divided into two branches, and extend toward the both widthwise end portions to subsequently extend along the peripheral end edge of the stage 17. Then, the wires 9 are turned back to reach the head-side terminals 18 and the front-side piezo-terminals 24.

Note that, of the wires 9, the portions extending between the first coupling portions 35 and the middle portion 16 are each formed in a linear shape along the widthwise direction.

The ground wires 13 are provided on the base portion 15 to have one ends thereof grounded and the other ends thereof electrically connected to the rear-side piezo-terminals 25.

As also shown in FIG. 3, a plurality of (two) front-side mounting portions 28 each as a mounting portion on which the front ends of the piezo-elements 23 are mounted are formed on both outsides of the middle portion 16 in the widthwise direction to be spaced apart from each other in correspondence to the front-side piezo-terminals 24. Specifically, each of the front-side mounting portions 28 includes the widthwise outer rear end portion of the stage 17, the insulating base layer 7 continued from the rear end portion of the stage 17 and extending rearwardly, and the front-side piezo-terminal 24.

A plurality of (two) rear-side mounting portions 29 each as the mounting portion on which the rear end portions of the piezo-elements 23 are mounted are formed on both outsides of the middle portion 16 in the widthwise direction to be spaced apart from each other in correspondence to the rear-side piezo-terminals 25. Specifically, each of the rear-side mounting portions 29 includes the widthwise outer front end portion of the base portion 15, the insulating base layer 7 continued from the front end portion of the base portion 15 and extending frontwardly, and the rear-side piezo-terminal 25.

The suspension board with circuit 1 includes the metal supporting board 5, the insulating base layer 7 formed on the metal supporting board 5, the conductive layer 6 formed on the insulating base layer 7, and the insulating cover layer 8 formed on the insulating base layer 7 so as to cover the conductive layer 6.

As shown in FIG. 1, the metal supporting board 5 is formed in a shape corresponding to the outer shape of the suspension board with circuit 1. The metal supporting board 5 is formed of a metal material such as, e.g., stainless steel, a 42-alloy, aluminum, a copper-beryllium alloy, or phosphor bronze. Preferably, the metal supporting board 5 is formed of stainless steel. The metal supporting board 5 has a thickness in a range of, e.g., not less than 15 μm, or preferably not less than 20 μm and, e.g., not more than 50 μm, or preferably not more than 30 μm.

As shown in FIGS. 1 to 2, the insulating base layer 7 is formed over the main body portion 3 and the gimbal portion 4 to correspond to the portion where the conductive layer 6 is formed, as shown in FIG. 3.

Specifically, the insulating base layer 7 is formed on the metal supporting board 5 in the main body portion 3 and is also formed in the board opening 11 and over the first coupling portions 35 and the middle portion 16 along the wires 9 in the gimbal portion 4.

Also, on the rear side of the stage 17, the insulating base layer 7 rearwardly protrudes from the rear end edge of the stage 17. Specifically, between the front end edge of each of the front-side piezo-terminals 24 and the rear end edge of the stage 17, the insulating base layer 7 which is slightly widthwise longer than the widthwise length of the front-side piezo-terminal 24 is formed.

Also, on the front side of the base portion 15, the insulating base layer 7 frontwardly protrudes from the front end edge of the base portion 15. Specifically, between the rear end edge of each of the rear-side piezo-terminals 25 and the front end edge of the base portion 15, the insulating base layer 7 which is slightly widthwise longer than the widthwise length of the rear-side piezo-terminal 25 is formed.

As shown in FIG. 2, the insulating base layer 7 is also formed in a pattern forming the second coupling portion 20.

The insulating base layer 7 is formed of an insulating material such as a synthetic resin such as, e.g., a polyimide resin, a polyamide imide resin, an acrylic resin, a polyether nitrile resin, a polyether sulfone resin, a polyethylene terephthalate resin, a polyethylene naphthalate resin, or a polyvinyl chloride resin. Preferably, the insulating base layer 7 is formed of the polyimide resin.

The insulating base layer 7 has a thickness in a range of, e.g., not less than 1 μm, or preferably not less than 3 μm and, e.g., not more than 35 μm, or preferably not more than 33 μm.

As described above, the conductive layer 6 is formed in a pattern including the external-side terminals 10 (FIG. 1), the head-side terminals 18, the front-side piezo-terminals 24, the rear-side piezo-terminals 25, and the wires 9.

The conductive layer 6 is formed of a conductive material such as, e.g., copper, nickel, gold, a solder, or an alloy thereof. The conductive layer 6 has a thickness in a range of, e.g., not less than 3 μm, or preferably not less than 5 μm and, e.g., not more than 50 μm, or preferably not more than 20 μm.

Each of the wires 9 has a width in a range of e.g., not less than 5 μm, or preferably not less than 8 μm and, e.g., not more than 200 μm, or preferably not more than 100 μm. Each of the external-side terminals 10, the head-side terminals 18, the front-side piezo-terminals 24, and the rear-side piezo-terminals 25 has a width and a length (longitudinal length) which are in a range of, e.g., not less than 20 μm, or preferably not less than 30 μm and, e.g., not more than 1000 μm, or preferably not more than 800 μm.

As shown in FIG. 1, the insulating cover layer 8 is formed over the main body portion 3 and the gimbal portion 4. As shown in FIG. 3, the insulating cover layer 8 is formed in a pattern including the conductive layer 6 in plan view.

Specifically, the insulating cover layer 8 is formed in a pattern which covers the upper surfaces of the wires 9, the front-side upper surfaces of the front-side piezo-terminals 24, and the rear-side upper surfaces of the rear-side piezo-terminals 25 and exposes the rear-side upper surfaces of the front-side piezo-terminals 24, the front-side upper surfaces of the rear-side piezo-terminals 25, and the upper surfaces of the external-side terminals 10 (see FIG. 1) and the head-side terminals 18.

The insulating cover layer 8 is formed of the same insulating material as the insulating material for forming the insulating base layer 7. The insulating cover layer 8 has a thickness in a range of, e.g., not less than 1 μm, or preferably not less than 3 μm and, e.g., not more than 40 μm, or preferably not more than 10 μm.

On the suspension board with circuit 1, the slider 26 and the piezo-elements 23 are mounted.

As shown by the imaginary line of FIG. 2 and in FIG. 3, the slider 26 is formed in a generally rectangular box shape in plan view. The front end portion of the slider 26 is bonded and fixed to the stage 17 via the stage adhesive layer 37.

The stage adhesive layer 37 has substantially the same thickness as the total thickness of, e.g., the insulating base layer 7, the conductive layer 6, and the insulating cover layer 8.

Thus, the front end portion of the slider 26 is fixed to the stage 17.

As shown in FIG. 2, the front end edge of the slider 26 is located along the head-side terminals 18. Specifically, the front end edge of the slider 26 is located on the rear side of the head-side terminals 18 with a minute space being interposed therebetween. As a result, as shown in FIG. 3, the magnetic head 27 mounted on the front end portion of the slider 26 is electrically connected to each of the head-side terminals 18 via a solder ball 19 shown by the imaginary line or the like.

As shown in FIG. 2, the rear end edge of the slider 26 is located so as to widthwise extend between the front-side piezo-terminals 24 and the rear-side piezo-terminals 25 and widthwise traverse the middle portion 16 at a middle point in the front-rear direction.

The plurality of (two) piezo-elements 23 are placed on both outsides of the middle portion 16 in the widthwise direction to be spaced apart from each other. Specifically, the piezo-elements 23 are extendable/contractible in the front-rear direction and each formed in a generally rectangular shape which is long in the front-rear direction in plan view. On the respective upper surfaces of the front end portions and the rear end portions of the piezo-elements 23, terminals 38 and 39 are formed.

The piezo-elements 23 are mounted to extend between the front-side piezo-terminals 24 and the rear-side piezo-terminals 25 so as to be extendable/contractible in the front-rear direction. Specifically, the piezo-elements 23 are placed such that the front end edges thereof coincide with the front end edges of the front-side piezo-terminals 24 in the front-rear direction and the rear end edges thereof coincide with the rear end edges of the rear-side piezo-terminals 25 in the front-rear direction.

The terminals 38 on the front end portions of the piezo-elements 23 and the terminals 39 on the rear end portions thereof are electrically connected to the front-side piezo-terminals 24 and the rear-side piezo-terminals 25 arranged to face each other with the conductive adhesive (and the conductive adhesive layer 30) being interposed therebetween. Thus, the piezo-elements 23 are fixed to the lower surfaces of the front-side piezo-terminals 24 and the rear-side piezo-terminals 25 via the conductive adhesive layer 30.

The conductive adhesive layer 30 is formed of the conductive adhesive and located between the lower surfaces of the front-side piezo-terminals 24 and the upper surfaces of the terminals 38 in the front end portions thereof and between the lower surfaces of the rear-side piezo-terminals 25 and the upper surfaces of the terminals 39 in the rear end portions thereof.

The conductive adhesive layer 30 is formed so as not to protrude outwardly from each of the terminals (front-side piezo-terminals 24 and rear-side piezo-terminals 25) and the piezo-elements 23 when projected in the thickness direction.

The conductive adhesive layer 30 has a thickness in a range of, e.g., not less than 5 μm, or preferably not less than 8 μm and, e.g., not more than 20 μm, or preferably not more than 15 μm.

The conductive adhesive may be any adhesive containing a conductive material. Examples of the conductive adhesive include a gold paste, a silver paste, a copper paste, a nickel paste, a tin paste, a palladium paste, and a solder. Preferably, in terms of volume resistance, the silver paste is used.

The conductive adhesive may be a heating type or an air-drying type.

When the conductive adhesive is a heating-type conductive adhesive, the heating temperature thereof is in a range of, e.g., not more than 200° C., or preferably not more than 180° C. By using a thermally-conductive adhesive having a heating temperature of not more than the foregoing heating temperatures, it is possible to suppress a reduction in the electrostatic capacitance of the piezo-elements 23.

Examples of such a conductive adhesive include a TK paste series available from Kaken Tech Co., Ltd., “CP-300” available from Hitachi Chemical Co., Ltd., and “RA FS 039” available from Toyochem Co., Ltd.

In each of the front-side mounting portions 28 and the rear-side mounting portions 29, an insulating adhesive layer 31 is formed. Specifically, the insulating adhesive layer 31 is placed adjacent to each of the front end portions and the rear end portions of the piezo-elements 23 so as to cover the piezo-elements 23 and the conductive adhesive layer 30.

The insulating adhesive layer 31 at the front end portion of each of the piezo-elements 23 is interposed between the rear end portion of the stage 17 and the front end portion of the piezo-element 23 to bond the stage 17 and the piezo-element 23 to each other. Specifically, the insulating adhesive layer 31 is interposed between the rear side surface of the stage 17, the lower surface of the insulating base layer 7, the front side surface of the conductive adhesive layer 30, and a part of the front side surface of the piezo-element 23 to bond the stage 17, the insulating base layer 7, the conductive adhesive layer 30, and the piezo-element 23 to each other. The insulating adhesive layer 31 is also placed so as to cover corner portions 32 between the rear side surface of the stage 17 and the lower surface thereof. The insulating adhesive layer 31 is formed to have a widthwise length which is generally the same as that of the insulating layer 7 and, specifically, slightly larger than the widthwise length of each of the front-side piezo-terminals 24.

On the rear side of each of the piezo-elements 23, the insulating adhesive layer 31 is interposed between the front end portion of the base portion 15 and the rear end portion of the piezo-element 23 to bond the base portion 15 and the piezo-element 23 to each other. Specifically, the insulating adhesive layer 31 is interposed between the front side surface of the base portion 15, the lower surface of the insulating base layer 7, the rear side surface of the conductive adhesive layer 30, and a part of the rear side surface of the piezo-element 23 to bond the base portion 15, the insulating base layer 7, the conductive adhesive layer 30, and the piezo-element 23 to each other. The insulating adhesive layer 31 is also placed so as to cover corner portions 33 between the front side surface of the base portion 15 and the lower surface thereof.

The insulating adhesive 31 layer is formed of an insulating adhesive.

The insulating adhesive contains an insulating adhesive composition and a metal ion scavenger.

As the insulating adhesive composition, any composition having an insulating property and used as an adhesive or a sealant may be used. The insulating adhesive composition contains a resin such as, e.g., a thermosetting resin or a thermoplastic resin. Preferably, the insulating adhesive composition contains a thermosetting resin.

Examples of the thermosetting resin include an epoxy resin, a urea resin, a melamine resin, a diallyl phthalate resin, a silicone resin, a phenol resin, a thermosetting acrylic resin, thermosetting polyester, thermosetting polyimide, and thermosetting urethane. Preferably, the epoxy resin is used.

Examples of the epoxy resin include an aromatic epoxy resin such as, e.g., a bisphenol type epoxy resin (such as, e.g., bisphenol A type epoxy resin, bisphenol F type epoxy resin, bisphenol S type epoxy resin, hydrogenated bisphenol A type epoxy resin, or dimer-acid-modified bisphenol type epoxy resin), a novolak type epoxy resin (such as, e.g., phenol novolak type epoxy resin, cresol novolak type epoxy resin, or biphenyl type epoxy resin), a naphthalene type epoxy resin, a fluorene type epoxy resin (such as, e.g., bisaryl fluorene type epoxy resin), or a triphenylmethane type epoxy resin (such as, e.g., trishydroxyphenylmethane type epoxy resin); a nitrogen-containing cyclic epoxy resin such as, e.g., triepoxypropyl isocyanurate(triglycidyl isocyanurate) or hydantoin epoxy resin; an aliphatic epoxy resin, an alicyclic epoxy resin (such as, e.g., dicyclo ring-type epoxy resin), a glycidyl ether type epoxy resin, and a glycidyl amine type epoxy resin.

Examples of the thermoplastic resin include polyolefin, an acrylic resin, polyester, polyvinyl acetate, an ethylene-acetate vinyl copolymer, polyvinyl chloride, polystyrene, polyacrylonitrile, polyamide (Nylon (registered trademark)), polycarbonate, polyacetal, polyethylene terephthalate, polyphenylene oxide, polyphenylene sulfide, polysulfone, polyether sulfone, polyether ether ketone, polyallyl sulfone, thermoplastic polyimide, thermoplastic polyurethane, polyamino-bismaleimide, polyamide-imide, polyether-imide, a bismaleimide-triazine resin, polymethyl pentene, a fluoride resin, a liquid crystal polymer, an ionomer, polyarylate, an olefin-vinyl alcohol copolymer, an acrylonitrile-ethylene-styrene copolymer, an acrylonitrile-butadiene-styrene copolymer, an acrylonitrile-styrene copolymer, and a butadiene-styrene copolymer.

As necessary, the insulating adhesive composition may contain an additive such as a solvent or a silane coupling agent.

As such an insulating adhesive composition, a commercially available product can be used. Specific examples thereof include a CEL-C series available from Hitachi Chemical Co., Ltd., “AH8455-345B” available from Namics Corporation, and “ThreeBond 2274B” available from Threebond Co., Ltd.

The metal ion scavenger can be determined as necessary depending on the type of a metal ion to be captured (i.e., conductive material contained in the conductive adhesive). Examples of the metal ion scavenger include a nitrogen-containing compound, a hydroxyl group-containing compound, a carboxyl group-containing compound, an inorganic cation exchanger, a chelate agent, and a phosphorus- or sulfur-containing compound. Preferably, the nitrogen-containing compound is used.

Examples of the nitrogen-containing compound include a nitrogen-containing heterocyclic compound such as a triazole compound, a tetrazole compound, a pyridyl compound, and a triazine compound. Preferably, the triazole compound is used.

Examples of the triazole compound include 1,2,3-triazole, 1,2,4-triazole, 1,2,3-benzotriazole, 1-{N,N-bis(2-ethylhexyl)aminomethyl}benzotriazole, and carboxybenzotriazole.

Examples of the tetrazole compound include 5-amino-1H-tetrazole and 5-phenyl-1H-tetrozole.

Examples of the pyridyl compound include 2,2′-bipyridyl and 1,10-phenanthroline.

Examples of the triazine compound include 1,3,5-triazine.

Examples of the hydroxyl group-containing compound include a quinol compound, a hydroxyanthraquinone compound, a polyphenolic compound, and a higher alcohol. Preferably, the quinol compound is used.

Examples of the quinol compound include hydroquinone and hydroxyquinol

Examples of the hydroxyanthraquinone compound include alizarin and anthrarufin.

Examples of the polyphenolic compound include tannin and tannin derivatives (gallic acid, methyl gallate, dodecyl gallate, and pyrogallol).

Examples of the higher alcohol include an alcohol having a linear or branched alky group having 6 or more carbon atoms, or preferably 6 to 18 carbon atoms.

Examples of the carboxyl group-containing compound include a carboxyl group-containing aromatic compound and a carboxyl group-containing aliphatic acid compound. Preferably, the carboxyl group-containing aromatic compound is used.

Examples of the carboxyl group-containing aromatic compound include a benzoic acid, a phthalic acid, a picolinic acid, and a pyrrol-2-carboxylic acid. Preferably, the benzoic acid is used.

Examples of the carboxyl group-containing aliphatic acid compound include a mono- or poly-carboxylic acid having 6 to 30 carbon atoms.

Examples of the inorganic cation exchanger include an oxidized hydrate of an element selected from antimony, bismuth, zirconium, titanium, tin, magnesium, and aluminum, an aluminosilicate, a polyvalent metal acid salt, a heteropoly acid, hydrotalcite, and hydroxyapatite. Preferably, an oxidized hydrate of an element selected from antimony, bismuth, zirconium, titanium, tin, magnesium, and aluminum is used.

As the oxidized hydrate, an oxidized hydrate of antimony or bismuth is preferably used. Specific examples thereof include antimony oxide hydrate and bismuth oxide hydrate.

Examples of the polyvalent metal acid salt include a phosphate of titanium, zirconium, aluminum, a rate-earth element, chromium (III), or the like.

Examples of the heteropoly acid include a phosphotungstic acid, a phosphomolybdic acid, and a silicomolybdic acid.

Examples of the chelate agent include an aminocarboxylic acid-type chelate agent and a phosphonic acid-type chelate agent. Preferably, the aminocarboxylic acid-type chelate agent is used.

Examples of the aminocarboxylic acid-type chelate agent include ethylenediaminetetraacetic acid, nitrilotriacetic acid, diethylenetriaminepentaacetic acid, hydroxyethylethylenediaminetriacetic acid, triethylenetetraminehexaacetic acid, 1,3-propanediaminetetraacetic acid, 1,3-diamino-2-hydroxypropanetetraacetic acid, hydroxyethyliminodiacetic acid, dihydroxyethylglycine, glycoletherdiaminetetraacetic acid, dicarboxymethylglutamic acid, and (S,S)-ethylenediaminedisuccinic acid. Preferably, diethylenetriaminepentaacetic acid is used.

Examples of the phosphonic acid-type chelate agent include a 1-hydroxyethylidenebisphosphonic acid, a nitrilotrismethylenephosphonic acid, a 2-phosphono-1,2,4-butanetricarboxilic acid, and an ethylenediaminetetramethylenephosphonic acid.

Examples of the phosphorus- or sulfur-containing compound include an organophosphate ester, an organophosphite ester, an organic sulfonate, an organic sulfur compound, a zinc dithiophosphate, and a phytic acid. Preferably, the organophosphite ester is used.

Examples of the organophosphate ester include trimethyl phosphate, triethyl phosphate, methyl acid phosphate, ethyl acid phosphate, and di-2-ethylhexyl acid phosphate.

Examples of the organophophite ester include diethyl phosphite, triethyl phosphite, triisooctyl phosphite, di-2-ethylhexyl hydrogen phosphite, and dioleyl hydrogen phosphite.

Examples of the organic sulfonate include alkali metal salts of an alkane sulfonic acid, an alkane disulfonic acid, an alkane trisulfonic acid, a benzene sulfonic acid, and the like and alkali metal salts of a polyvinyl sulfonic acid, copolymers thereof, and the like.

Examples of the organic sulfur compound include 2,5-dimercapto-1,3,4-thiadiazole.

The content of the metal ion scavenger based on 100 parts by mass of the insulating adhesive composition is in a range of, e.g., not less than 0.05 parts by mass, or preferably not less than 0.1 parts by mass and, e.g., not more than 50 parts by mass, preferably not more than 30 parts by mass, or more preferably not more than 20 parts by mass.

By limiting the content of the metal scavenger to a value of not less than the foregoing lower limit, it is possible to effectively capture metal ions (e.g., copper ions or silver ions) and improve the reliability of the electrical connection between the piezo-elements 23 and the terminal portions 24 or 25. On the other hand, by limiting the content of the metal ion scavenger to a level of not more than the foregoing upper limit, it is possible to capture ions, while suppressing the peeling of the insulating adhesive, and also improve heat resistance and cost.

The insulating adhesive composition can be prepared by blending the insulating adhesive composition and the metal ion scavenger.

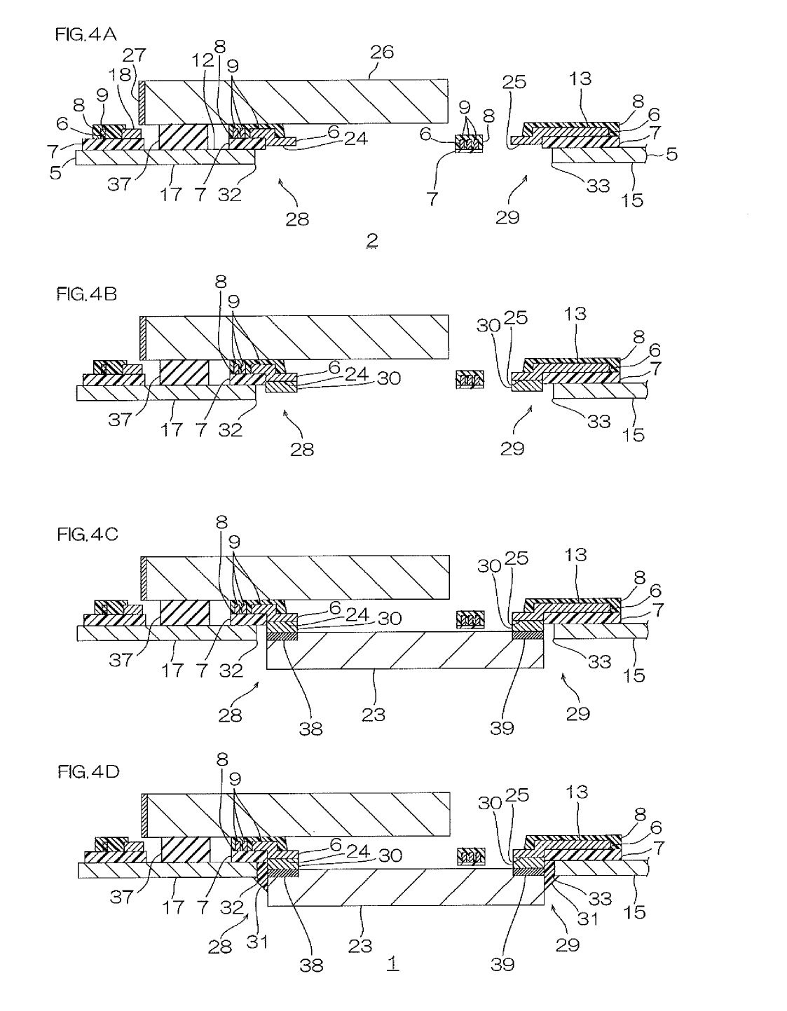

To obtain the suspension board with circuit 1, first, as shown in FIG. 4A, the suspension board with circuit 2 (suspension board with slider) on which the slider 26 is mounted is prepared.

The suspension board with circuit 2 on which the slider 26 is mounted can be produced by referencing, e.g., Japanese Unexamined Patent No. 2012-99204, Japanese Unexamined Patent No. 2011-129220, and the like.

Then, as shown in FIG. 4B, on the lower surfaces of the front-side piezo-terminals 24 and the rear-side piezo-terminals 25, the conductive adhesive layer 30 is placed.

Specifically, the conductive adhesive is placed on the entire lower surfaces of the front-side piezo-terminals 24 and the entire lower surfaces of the rear-side piezo-terrninals 25.

Examples of a method of placing the conductive adhesive in chide a coating method, an ejection method, and the like.

Then, as shown in FIG. 4C, the piezo-elements 23 are mounted on the suspension board with circuit 2. Specifically, the upper surfaces of the terminals 38 in the front end portions of the piezo-elements 23 and the upper surfaces of the terminals 39 in the rear end portions thereof are brought into contact with the conductive adhesive placed on the lower surfaces of the front-side piezo-terminals 24 and the rear-side piezo-terminals 25.

At this time, when the conductive adhesive is a heating-type conductive adhesive, a heat treatment step is performed.

A heat treatment temperature is in a range of, e.g., not more than 200 CC, or preferably not more than 180° C. and, e.g., not less than 100° C., or preferably not less than 120° C.

A heat treatment time is in a range of, e.g., not less than 10 minutes, or preferably not less than 20 minutes and, e.g., not more than 5 hours, or preferably not more than 3 hours.

As necessary, the heat treatment step may be performed at multiple stages (i.e., in a plurality of temperature ranges).

In this manner, the piezo-elements 23 are electrically connected to the suspension board with circuit 2 via the conductive adhesive layer 30. To the piezoelectric elements 23, electricity is supplied via the front-side piezo-terminals 24, and the voltage thereof is controlled to extend/contract the piezo-elements 23.

Then, as shown in FIG. 4D, the insulating adhesive layer 31 is placed on each of the front-side mounting portions 28 and the rear-side mounting portions 29.

Specifically, the insulating adhesive is placed so as to come in contact with the rear side surface of the stage 17, the lower surface of the insulating base layer 7, the front side surface of the conductive adhesive layer 30, and a part of the front side surface of each of the piezo-elements 23. At this time, the insulating adhesive is also placed so as to cover the corner portions 32 of the stage 17.

The insulating adhesive is also placed so as to come in contact with the front side surface of the base portion 15, the lower surface of the insulating base layer 7, the rear side surface of the conductive adhesive layer 30, and a part of the rear side surface of each of the piezo-elements 23. At this time, the insulating adhesive is placed so as to cover the corner portions 33 of the base portion 15.

Examples of a method of placing the insulating adhesive include a coating method, an ejection method, and the like.

When the insulating adhesive contains a thermosetting resin, a heat treatment step is performed after the placement.

A heat treatment temperature is in a range of, e.g., not more than 200° C., or preferably not more than 180° C. and, e.g., not less than 100° C., or preferably not less than 120° C.

A heat treatment time is in a range of, e.g., not less than 10 minutes, or preferably not less than 20 minutes and, e.g., not more than 5 hours, or preferably not more than 3 hours.

As necessary, the heat treatment step may be performed at multiple stages (i.e., in a plurality of temperature ranges).

In this manner, the piezo-elements 23 are bonded to the stage 17, the base portion 15 and the insulating base layer 7 of the suspension board with circuit 2 via the insulating adhesive layer 31.

The suspension board with circuit 1 includes the piezo-elements 23 and the front-side mounting portions 28 having the front-side piezo-terminals 24 to be electrically connected to the piezo-elements 23. The piezo-elements 23 and the front-side mounting portions 28 are bonded to each other via the insulating adhesive layer 31 (insulating adhesive containing the metal ion scavenger).

This allows the metal ion scavenger to capture the metal ions contained in the connection portion (conductive adhesive layer 30) electrically connecting the piezo-elements 23 and the front-side mounting portions 28. As a result, it is possible to inhibit the metal ions from moving or flowing to the outside of the front-side mounting portions 28. Therefore, it is possible to prevent a short circuit and improve the reliability of the electrical connection between the piezo-elements 23 and the front-side piezo-terminals 24.

The suspension board with circuit 1 also includes the piezo-elements 23 and the rear-side mounting portions 29 having the rear-side piezo-terminals 25 to be electrically connected to the piezo-elements 23. The piezo-elements 23 and the rear-side mounting portions 29 are bonded to each other via the insulating adhesive layer 31 (insulating adhesive containing the metal ion scavenger).

This allows the metal ion scavenger to capture the metal ions contained in the connection portion (conductive adhesive layer 30) electrically connecting the piezo-elements 23 and the rear-side mounting portions 29. As a result, it is possible to inhibit the metal ions from moving or flowing to the outside of the rear-side mounting portions 29. Therefore, it is possible to prevent a short circuit and improve the reliability of the electrical connection between the piezo-elements 23 and the rear-side piezo-terminals 25.

In the suspension board with circuit 1, the piezo-elements 23 and the front-side and rear-side piezo-terminals 24 and 25 are disposed to face each other with the conductive adhesive layer 30 being interposed therebetween. The insulating adhesive layer 31 is disposed adjacent to the piezo-elements 23 and the conductive adhesive layer 30 so as to cover the piezo-elements 23 and the conductive adhesive layer 30.

This allows the path along which the metal ions contained in the conductive adhesive layer 30 move toward the metal supporting board 5 (stage 17 or base portion 15) to be included in the insulating adhesive layer 31. As a result, by reliably capturing the metal ions moving toward the metal supporting board 5 (stage 17 or base portion 15), it is possible to prevent a short circuit and further improve the reliability of the electrical connection.

In addition, the piezo-elements 23 are located adjacent to the insulating adhesive layer 31 and connected mechanically solidly to the front-side mounting portions 28 and the rear-side mounting portions 29 via the insulating adhesive layer 31. This can reliably suppress the breakage of the piezo-elements resulting from the extension/contraction thereof.

Moreover, since the insulating adhesive layer 31 covers the conductive adhesive layer 30, it is possible to reduce the corrode of the conductive adhesive layer 30 due to ambient air.

In particular, the insulating adhesive layer 31 is placed so as to be bonded to the rear side surface of the stage 17, the lower surface of the insulating base layer 7, the front side surface of the conductive adhesive layer 30, and a part of the front side surface of each of the piezo-elements 23 and cover the corner portions 32 of the stage 17. Consequently, the insulating adhesive layer 31 is reliably bonded to the piezo-elements 23 and the front-side mounting portions 28 of the suspension board with circuit over a wide range. The insulating adhesive layer 31 is also placed so as to be bonded to the front side surface of the base portion 15, the lower surface of the insulating base layer 7, the rear side surface of the conductive adhesive layer 30, and a part of the rear side surface of each of the piezo-elements 23 and cover the corner portions 33 of the base portion 15. Consequently, the insulating adhesive layer 31 is reliably bonded to the piezo-elements 23 and the rear-side mounting portions 29 of the suspension board with circuit over a wide range. As a result, the piezo-elements 23 are connected mechanically solidly to the front-side mounting portions 28 and the rear-side mounting portions 29 of the suspension board with circuit 1. This can reliably suppress the breakage of the piezo-elements 23 resulting from the extension/contraction thereof.

Note that, in the embodiment of FIG. 3, the front-side mounting portions 28 and the rear-side mounting portions 29 are each bonded to the piezo-element 23 via the insulating adhesive layer 31 (insulating adhesive containing the metal ion scavenger). However, e.g., either the front-side mounting portions 28 or the rear-side mounting portions 29 may also be bonded to the piezo-elements 23 via the insulating adhesive layer 31 (insulating adhesive containing the metal ion scavenger).

Also, in the embodiment of FIG. 3, the conductive adhesive layer 30 is placed so as not to protrude outwardly from each of the terminals and the piezo-elements 23 when projected in the thickness direction. However, the conductive adhesive layer 30 can also be placed so as to protrude outwardly from each of the terminals and the piezo-elements 23 when projected in the thickness direction.

That is, in this embodiment, with regard to the front-side piezo-terminal 24, the front end edge of the conductive adhesive layer 30 is located on the front side of the front end edge of the piezo-element 23 and the piezo-terminal 24 in the longitudinal direction and the conductive adhesive layer 30 covers a part of the insulating base layer 7 and a part of the front-end side surface of the piezo-element 23. With regard to the rear-side piezo-terminal 25, the rear end edge of the conductive adhesive layer 30 is located on the rear side of the rear end edge of the piezo-element 23 and the rear-side piezo-terminal 25 in the longitudinal direction and the conductive adhesive layer 30 covers a part of the insulating base layer 7 and a part of the rear-end side surface of the piezo-element 23.

Preferably, as in the embodiment of FIG. 3, the conductive adhesive layer 30 is placed so as not to protrude outwardly from each of the terminals and the piezo-elements 23 when projected in the thickness direction. This can limit the contact portion between the conductive adhesive layer 30 and the insulating adhesive layer 31 to the side surfaces of the conductive adhesive layer 30 and minimize the area over which metal ions are discharged from the conductive adhesive layer 30 into the insulating adhesive layer 31. As a result, it is possible to reduce the number of the metal ions moved to the insulating adhesive layer 31 and further improve the connection reliability.

Also, in the embodiment of FIG. 3, each of the front-side piezo-terminals 24 or the rear-side piezo-terminals 25 is formed such that the lower surface thereof is located slightly above the lower surface of the insulating base layer 7 located adjacent thereto. However, each of the front-side piezo-terminals 24 or the rear-side piezo-terminals 25 can also be formed such that the lower surface thereof is flush with the lower surface of the insulating base layer 7 located adjacent thereto.

Preferably, each of the front-side piezo-terminals 24 or the rear-side piezo-terminals 25 is formed such that the lower surface thereof is located slightly above the lower surface of the insulating base layer 7 located adjacent thereto.

This allows a stepped portion to be formed in the boundary between the lower surface of each of the front-side piezo-terminals 24 or the rear-side piezo-terminals 25 and the lower surface of the insulating base layer 7 located adjacent thereto. As a result, it is possible to easily form the conductive adhesive layer 30 only under the terminals (front-side piezo-terminals 24 and the rear-side piezo-terminals 25) and more reliably place the conductive adhesive layer 30 such that the conductive adhesive layer 30 does not protrude outwardly from the terminals and the piezo-elements 23. In addition, since the conductive adhesive layer 30 is located above the insulating adhesive layer 31, it is also possible to reduce the area of the boundary between the conductive adhesive layer 30 and the insulating adhesive layer 31. This can further improve the connection reliability.

### EXAMPLES

While in the following, the present invention is described more specifically with reference to Examples and Comparative Example, the present invention is by no means limited thereto. Numerical values in Examples shown below can be replaced with the numerical values (i.e., upper limit values or lower limit values) shown in the embodiment described above.

### Example 1

The suspension board with circuit 2 on which the slider 26 shown in FIG. 4A was mounted was prepared.

Then, as a conductive adhesive, silver paste (TK paste CR-3520 available from Kaken Tech Co., Ltd.) was prepared.

Also, 100 parts by mass of an epoxy-based liquid sealant (CEL-C-5020 available from Hitachi Chemical Co., Ltd.) serving as an insulating adhesive composition and 2 parts by mass of 1,2,3-trizazole serving as a metal ion scavenger were blended to prepare an insulating adhesive.

Then, as shown in FIG. 4B, a silver paste was applied to the lower surface of each of the front-side piezo-terminals 24 and the rear-side piezo-terminals 25. Then, the piezo-elements 23 were stacked on the silver paste, heated at 130° C. for 30 minutes, and then heated at 180° C. for 60 minutes. Thus, using the conductive adhesive layer 30 (having a thickness of 10 μm) formed from the silver paste, electrical connection was provided between the piezo-elements 23 and the suspension board with circuit 2 (FIG. 4C).

Then, as shown in FIG. 4D, the insulating adhesive was applied to the rear side surface of the stage 17, the lower surface of the insulating base layer 7, the front side surface of the conductive adhesive layer 30, and a part of the front side surface of each of the piezo-elements 23 so as to cover the corner portions 32 of the stage 17. The insulating adhesive was also applied to the front side surface of the base portion 15, the lower surface of the insulating base layer 7, the rear side surface of the conductive adhesive layer 30, and a part of the rear side surface of each of the piezo-elements 23 so as to cover the corner portions 33 of the base portion 15.

Then, the insulating adhesive was heated at 120° C. for 20 minutes and then heated at 150° C. for 120 minutes to form the insulating adhesive layer 31.

In this manner, the suspension board with circuit 1 on which the piezo-elements 23 were mounted of Example 1 was produced.

### Examples 2 to 9 and Comparative Example 1

The suspension boards with circuits 1 on which the piezo-elements 23 were mounted were produced in the same manner as in Example 1 except that the metal ion scavenger in the insulating adhesive was changed to the formula shown in Table 1.

(Connection Reliability)

In each of the suspension boards with circuits 1 in Examples and Comparative Example, a DC voltage of 60 V was applied to the piezo-elements 23 for 500 hours in an atmosphere at 85° C. and 85% RH. Then, the presence/absence of an ion migration phenomenon in which silver moves to the interface between the insulating adhesive or the insulating base layer and the metal supporting board was checked by cross-sectional SEM observation.

The suspension board with circuit 1 in which the ion migration phenomenon was not recognized in the metal supporting board was evaluated as excellent. The suspension board with circuit 1 in which the ion migration phenomenon was not recognized in the metal supporting board but local peeling of the insulating adhesive was recognized was evaluated as good. The suspension board with circuit 1 in which the ion migration phenomenon was recognized in the metal supporting board was evaluated as poor. The results are shown in Table 1.

TABLE 1

| | Metal Ion Scavenger | | Evaluation of |
|---|---|---|---|
| | Type | Blending Ratio* | Connection |
| Example 1 | 1,2,3-Triazole | 2 | Excellent |
| Example 2 | 1,2,3-Triazole | 0.1 | Excellent |
| Example 3 | 1,2,3-Triazole | 20 | Excellent |
| Example 4 | 1,2,3-Triazole | 50 | Good |
| Example 5 | Hydroxyquinol | 2 | Excellent |
| Example 6 | Benzoic Acid | 2 | Excellent |
| Example 7 | Antimony(V) Oxide | 2 | Excellent |
| | Hydrate | | |
| Example 8 | Chelest 3PA | 2 | Excellent |
| Example 9 | ChelexH8 | 2 | Excellent |
| Comparative | — | 0 | Poor |
| Example 1 | | | |

*shows parts by mass based on 100 parts by mass of epoxy-based liquid sealant

General designations and the like in Table 1 are shown below.

Chelest 3PA (trade name): diethylenetriaminepentaacetic acid available from Chelest Corporation

ChelexH8 (trade name): di-2-ethylhexyl hydrogen phosphite available from SC Organic Chemical Co., Ltd.

While the illustrative embodiments of the present invention are provided in the above description, such is for illustrative purpose only and it is not to be construed limitative. Modification and variation of the present invention which will be obvious to those skilled in the art is to be covered by the following claims.

What is claimed is:

1. A suspension board with circuit, comprising:
an electronic element; and
a mounting portion having a terminal portion electrically connected to the electronic element, wherein
the electronic element and the mounting portion are bonded to each other via an adhesive containing a metal ion scavenger.

2. A suspension board with circuit according to claim 1, wherein the adhesive containing the metal ion scavenger is an insulating adhesive.

3. A suspension board with circuit according to claim 2, wherein the electronic element and the terminal portion are bonded to each other via a conductive adhesive.

4. A suspension board with circuit according to claim 3, wherein
the electronic element and the terminal portion are placed to face each other with the conductive adhesive being interposed therebetween, and
the insulating adhesive is placed adjacent to the electronic element and the conductive adhesive so as to cover the electronic element and the conductive adhesive.

5. A suspension board with circuit according to claim 1, wherein the metal ion scavenger is at least one selected from the group consisting of a nitrogen-containing compound, a hydroxyl group-containing compound, a carboxyl group-containing compound, an inorganic cation exchanger, a chelate agent, and a phosphorus- or sulfur-containing compound.

6. A suspension board with circuit according to claim 5, wherein the nitrogen-containing compound is at least one selected from the group consisting of a triazole compound, a tetrazole compound, a pyridyl compound, and a triazine compound.

7. A suspension board with circuit according to claim 5, wherein the hydroxyl group-containing compound is at least one selected from the group consisting of a quinol compound, a hydroxyanthraquinone compound, a polyphenolic compound, and a higher alcohol.

8. A suspension board with circuit according to claim 5, wherein the carboxyl group-containing compound is at least one selected from the group consisting of a carboxyl group-containing aromatic compound and a carboxyl group-containing aliphatic acid compound.

9. A suspension board with circuit according to claim 5, wherein the inorganic cation exchanger is at least one selected from the group consisting of an oxidized hydrate of an element selected from antimony, bismuth, zirconium, titanium, tin, magnesium, and aluminum, an aluminosilicate, a polyvalent metal acid salt, a heteropoly acid, hydrotalcite, and hydroxyapatite.

10. A suspension board with circuit according to claim 5, wherein the chelate agent is at least one selected from the group consisting of an aminocarboxylic acid-type chelate agent and a phosphonic acid-type chelate agent.

11. A suspension board with circuit according to claim 5, wherein the phosphorus- or sulfur-containing compound is at least one selected from the group consisting of an organophophate ester, an organophosphite ester, an organic sulfonate, an organic sulfur compound, a zinc dithiophosphate, and a phytic acid.

12. A suspension board with circuit according to claim 2, wherein
the insulating adhesive contains an insulating adhesive composition and the metal ion scavenger, and
a content of the metal ion scavenger based on 100 parts by mass of the insulating adhesive composition is not less than 0.1 parts by mass and not more than 50 parts by mass.
